(19) United States
(12) Patent Application Publication
(10) Pub. No.: US 2023/0227996 A1
(43) Pub. Date: Jul. 20, 2023

(54) METHOD OF FORMING SHADOW WALLS FOR FABRICATING PATTERNED STRUCTURES

(71) Applicant: Microsoft Technology Licensing, LLC, Redmond, WA (US)

(72) Inventors: Jason Petros Heinrich JUNG, Eindhoven (NL); Roy Leonardus Maria OP HET VELD, Eindhoven (NL)

(73) Assignee: Microsoft Technology Licensing, LLC, Redmond, WA (US)

(21) Appl. No.: 17/996,369

(22) PCT Filed: Apr. 22, 2020
(86) PCT No.: PCT/EP2020/061144

§ 371 Date: Oct. 17, 2022

(51) Int. Cl. C30B 23/04; H10N 60/01; C30B 29/42; C30B 25/04

(52) U.S. Cl. CPC C30B 23/04; C30B 25/04; C30B 29/42; H10N 60/01

(57) ABSTRACT

A method comprising: forming a first mask over a substrate; forming one or more shadow walls in the openings of the first mask by selective area growth; forming a second mask over the substrate and shadow walls; forming a second material in the openings of the second mask by selective area growth; and depositing a layer of deposition material by angled deposition over parts of the substrate, shadow walls and second material, whereby regions shadowed by the shadow walls are left uncoated. In embodiments the second material may be a semiconductor and the deposition material may be a superconductor, and the method may be used to form one or more semiconductor-superconductor nanowires for inducing majorana zero modes as part of a quantum computing device.

### BACKGROUND

Topological quantum computing is based on the phenomenon whereby non-abelian anyons, in the form of “Majorana zero modes” (MZMs), can be formed in regions where a semiconductor is coupled to a superconductor. A non-abelian anyon is a type of quasiparticle, meaning not a particle per se, but an excitation in an electron liquid that behaves at least partially like a particle. A MZM is a particular bound state of such quasiparticles. Under certain conditions, these states can be formed close to the semiconductor-superconductor interface in a nanowire formed from a length of semiconductor coated with a superconductor. When MZMs are induced in the nanowire, it is said to be in the “topological regime”. To induce this, this requires a magnetic field, conventionally applied externally, and also cooling of the nanowire to a temperature that induces superconducting behaviour in the superconductor material. It may also involve gating a part of the nanowire with an electrostatic potential.

By forming a network of such nanowires and inducing the topological regime in parts of the network, it is possible to create a quantum bit (qubit) which can be manipulated for the purpose of quantum computing. A quantum bit, or qubit, is an element upon which a measurement with two possible outcomes can be performed, but which at any given time (when not being measured) can in fact be in a quantum superposition of the two states corresponding to the different outcomes.

To induce a MZM the device is cooled to a temperature where the superconductor (e.g. Aluminium, Al) exhibits superconducting behaviour. The superconductor causes a proximity effect in the adjacent semiconductor, whereby a region of the semiconductor near the interface with the superconductor also exhibits superconducting properties. I.e. a topological phase behaviour is induced in the adjacent semiconductor as well as the superconductor. It is in this region of the semiconductor where the MZMs are formed.

Another condition for inducing the topological phase where MZMs can form is the application of a magnetic field in order to lift the spin degeneracy in the semiconductor. Degeneracy in the context of a quantum system refers to the case where different quantum states have the same energy level. Lifting the degeneracy means causing such states to adopt different energy levels. Spin degeneracy refers to the case where different spin states have the same energy level. Spin degeneracy can be lifted by means of a magnetic field, causing an energy level split between the differently spin-polarized electrons. This is known as the Zeeman effect. Typically the magnetic field is applied by an external electromagnet. However it is also possible to use a layer ferromagnetic insulator disposed between the superconductor and semiconductor in order to internally apply the magnetic field for lifting the spin degeneracy, without the need for an external magnet.

Inducing MZMs also involves gating the nanowire with an electrostatic potential to control the carrier density in the nanowire. The terminals for applying this potential are referred to as the gates.

Structures such as the semiconductor cores of a network of nanowires can be formed on a substrate by means of a process known as selective area growth (SAG), which refers to selective epitaxial growth through an amorphous mask. Epitaxy is a known deposition technique that comprises growing one crystalline material on another crystalline material. The first material acts as a seed crystal for the second material being grown on the first. The growth is performed selectively by forming a patterned mask over a layer of the first material (e.g. a crystalline substrate) and growing the deposited material (e.g. the semiconductor of the nanowires) in the regions left exposed by the mask. Because the mask is amorphous the deposed material does not grow on the mask but only in the openings where the underlying crystalline substrate is exposed. Example techniques for the epitaxial deposition itself include, for example, electron-beam physical vapour deposition, chemical beam epitaxy, metal-organic chemical vapour deposition, plasma-enhanced chemical vapour deposition, atomic layer deposition, and molecular beam epitaxy.

Forming a device comprising a network of nanowires will involve selectively patterning the layer of superconducting material to form superconducting “islands” and isolate electrically some parts from others. For instance, the MZMs form at the endpoints of the semiconductor/superconductor heterostructure of the nanowire where the semiconductor and superconductor meet, and they are measured through tunnelling spectroscopy. So an area where the semiconductor is not covered by a superconductor is required.

One form of selective patterning technology that can be used for this is a stencil mask, whereby a stencil is mechanically held aloft over the substrate and mechanically aligned, and the superconducting material (e.g. Al) is deposited through the openings in the mask (a positive image). However stencil masks are difficult to align to the necessary level of accuracy.

Another example is selective etching, whereby a uniform layer of the material is deposited over the whole of the underlying structure, and then the unwanted parts are etched away (a negative image). However this etching step can degrade the quality of the semiconductor structure underneath.

A third alternative which mitigates these issues is to use shadow walls. In this case, selective patterning of the superconducting material (e.g. Al) is achieved using one or more “shadow walls” in conjunction with an angled deposition beam. A shadow wall protrudes outwardly from the surface of a substrate on the side being worked, in order to define an adjacent shadow region in which deposition is prevented due to the shadow wall inhibiting the passage of the angled deposition beam. Hence, deposition will not occur on a surface portion of a semiconductor structure within the shadow region. Shadow walls can thus be used to achieve selective patterning of semiconductor structures and have various benefits over the alternatives mentioned above.

The shadow wall technique can also be used in the fabrication of other kinds of nanostructures, not just nanowires in quantum computing devices. It can be used in any fabrication where the creation of heterostructures is required in selective areas by means of a directional beam deposition.

### SUMMARY

As discussed, there are various existing techniques for patterning a layer of material that is to be deposited over some other underlying structure. However all of these have some downside or another, including methods of forming shadow walls. For instance, shadow walls can be formed from the same mask dielectric that is used to define the structure of the underlying semiconductor of the nanowires. However, this requires to start with a very thick mask and then perform two selective etching steps: a first to etch the mask to the depth of the walls, and a second to define the openings in which the nanowires will be grown. However the deep etching needed to define the walls is hard to control and can end up damaging the substrate.

It is recognized herein that it would be desirable to provide an alternative method of forming shadow walls for the purpose of patterning or selective deposition.

According to one aspect disclosed herein, there is provided a method of fabricating a device, the method comprising: forming a first layer of amorphous mask material over a substrate; patterning the first layer of mask material over the substrate to form a first mask having a pattern of one or more first openings therethrough, the substrate having a crystalline surface at least in some areas including areas exposed by the openings; and forming one or more shadow walls in the openings of the first mask by selective area growth of a first crystalline material. The method further comprises: forming a second layer of amorphous mask material over the substrate and shadow walls; patterning the second layer of mask material to form a second mask having a pattern of one or more openings therethrough, the substrate having a crystalline surface also in areas exposed by the second openings; and forming a second crystalline material in the openings of the second mask by selective area growth. the method then comprises depositing a layer of deposition material by angled deposition over parts of the substrate, shadow walls and second crystalline material, whereby regions shadowed by the shadow walls are left uncoated.

In embodiments the second crystalline material is a semiconductor such as InSb and the deposition material is a superconducting material such as Al. The method may be used to form a quantum device comprising one or more nanowires, with the cores of the nanowires being formed from the semiconductor material and the superconducting coating being formed from the deposition material.

This two-stage approach provides improved control over the wall height and definition of the semiconductor (e.g. wire diameter) whilst mitigating damage to the semiconductor, or similarly for any other such underlying second crystalline material.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Nor is the claimed subject matter limited to implementations that solve any or all of the disadvantages noted herein.

### BRIEF DESCRIPTION OF THE DRAWINGS

To assist understanding of embodiments of the present disclosure and to show how such embodiments may be put into effect, reference is made, by way of example only, to the accompanying drawings in which:

FIG. 1 is a flow chart showing a method of fabricating a nanostructure according to exemplary embodiments disclosed herein,

FIGS. 2A-C give schematic side views of the nanostructure at various stages in the fabrication method of FIG. 1,

FIG. 3 shows a schematic isometric view of the nanostructure fabricated according to the method of FIGS. 1 and 2A-C,

FIG. 4 gives a schematic top-down view of another example nanostructure which may be fabricated using embodiments of the techniques disclosed herein,

FIG. 5 is a scanning electron micrograph of an example nanostructure fabricated using embodiments of the techniques disclosed herein, and

FIG. 6 gives schematic isometric view of another example nanostructure which may be fabricated using embodiments of the techniques disclosed herein.

### DETAILED DESCRIPTION OF EMBODIMENTS

The following describes a method of forming bottom-up selective area grown shadowing objects by selective material deposition. This may be exploited to allow for in-situ deposition of the disposition material.

In the embodiments described below, the disclosed method is applied to the fabrication of semiconductor-superconductor nanostructures such as nanowires for inducing MZMs. Nonetheless, the disclosed fabrication method also has other useful applications, and can, in general, be applied with any SAG structures to be selectively patterned with a layer of deposition material. E.g. the method may alternatively be used in the fabrication of optical devices, spintronic devices or classical electronic devices.

For good quality devices it is desirable to be able to fabricate clean interfaces between the materials in heterostructures, such as between the semiconductor and superconductor in a nanowire. Traditionally top-down approaches involving etching are used to confine these heterostructures to specific areas. These often very aggressive processes bear the risk of causing etching-damage on the semiconductor surface, giving rise to scattering sites. This is particularly problematic for quantum applications, as these scattering sites negatively affect carrier mobility and the coherence length of devices.

Desired nanostructure patterns are most commonly dry or wet etched, which has the aforementioned issue of quality deterioration as a consequence. This becomes especially apparent in more sensitive applications, e.g. quantum materials.

Lift-off methods using a sacrificial material, e.g. photoresist, to pattern the target material suffer from the same problem as they involve chemical processing on the material interfaces.

An alternative method to achieve selective metal deposition is stencil lithography, which uses a shadow mask with nanometer size apertures. Difficulties of the mask alignment and blurring of the transferred pattern due to the geometric setup of the evaporation prevent this method from being applicable if high accuracy is needed.

Shadow walls avoid the need for top-down patterning of the deposition material itself. However, conventionally such walls are formed from the dielectric mask material (the same mask as used for SAG of the semiconductor). In this case extensive etching is still required in order to define the wall structures. In other words top-down etched walls are used as shadowing objects, but during this etching procedure the substrate is again damaged, which can be detrimental to the subsequent material growth.

The disclosed method of bottom-up selective area grown shadowing objects, on the other hand, allows for clean selective material deposition including metals, superconductors, dielectrics and combinations thereof.

Other prior techniques have used the semiconductor cores of the nanowires themselves as shadowing objects. E.g. one or two facets of the nanowire facing the deposition beam are coated with the incident superconducting material (e.g. Al) in order to leave a shadowed facet uncoated on the other side of the nanowire, which is thus unshielded and so can be used to allow gating of the nanowire via a side gate. However this approach is not very flexible as it does not allow the designer to define any arbitrary pattern that may be desired in the deposited Al, e.g. for purposes other than side gating.

The presently disclosed method of using separate selective area grown structures, on the other hand, adds the precise control over the shadow region necessary to keep the method flexible and scalable.

The method disclosed herein mitigates the amount etching. Instead it takes advantage of directional growth methods and uses bottom-up selective area grown structures as shadowing objects to obtain selective deposition. The ability to lithographically define the position and area of the objects, and to grow a predefined height, ensures precise control of the shadowed region and warrants scalability. The whole material growth process can furthermore take place in situ, i.e. without breaking the vacuum, leading to clean oxide free material interfaces.

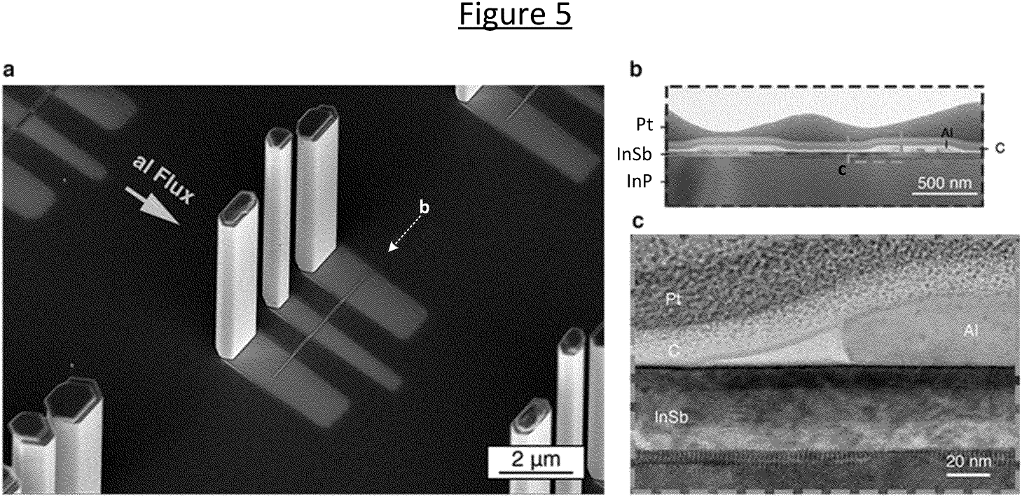

An example application of this method is demonstrated in FIG. 5. This shows an in-plane grown InSb nanowire with two separate Al islands deposited through shadow evaporation. Here selective area grown InP pillars are used as the shadowing objects. The resulting hybrid semiconductor-superconductor nanostructure can be used for Majorana based applications in topological quantum computation.

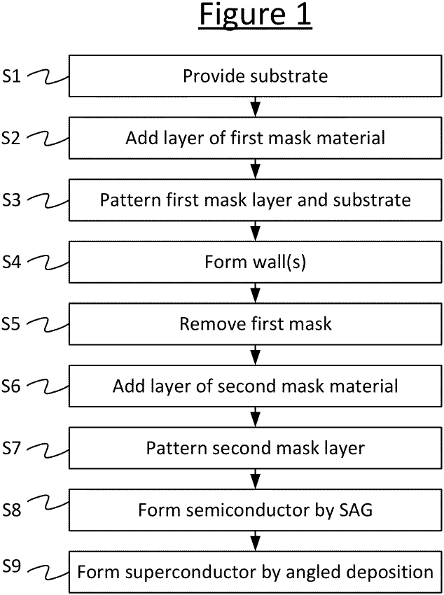

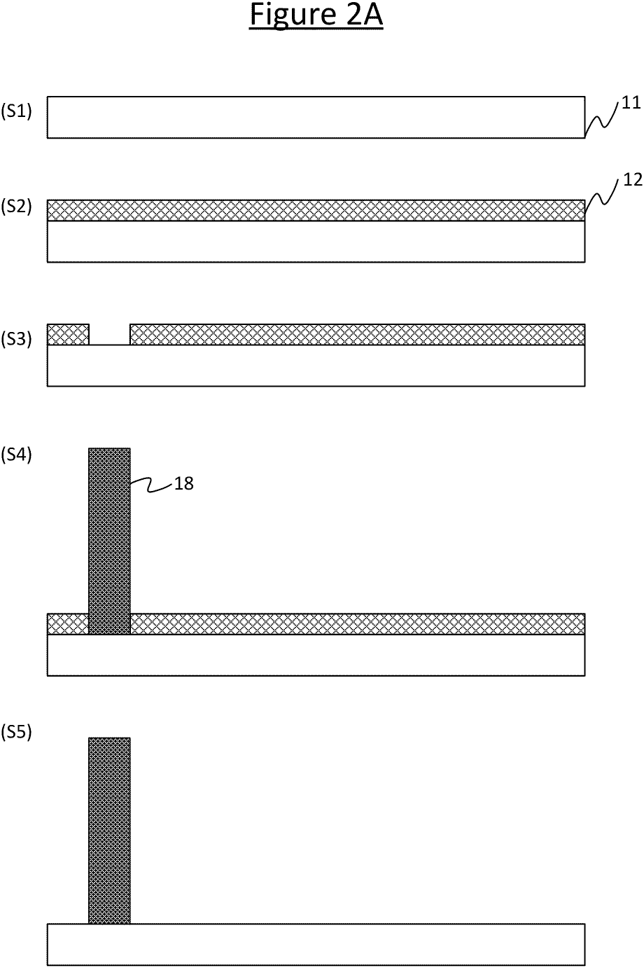

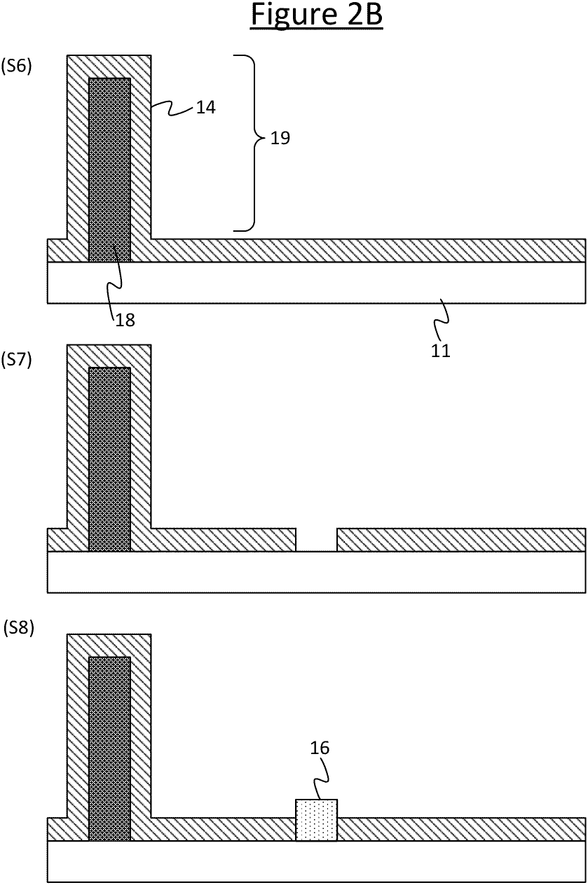

FIG. 1 is a flow chart of a method according to exemplary embodiments of the present disclosure. FIGS. 2A-C show a side view of the device being fabricated during various stages of the method.

The device to be fabricated will comprise: a substrate 11, a wall structure 19 (comprising one or more shadow walls 18), the semiconductor cores 16 of the nanowires, and the superconducting coating 17 over part or all of each semiconductor core 16.

On a point of terminology, “over” herein may mean either formed directly on, or indirectly over with any one or more intermediate layers in between. “On” herein means directly on, i.e. in contact with, without any intermediate layer. Note also that the terms “on” or “over” or such like, as used herein, do not necessarily imply a particular orientation relative to gravity (in some growth chambers the device could be fabricated upside down compared to the orientation shown in the figures). Rather, they refer to the position relative to the side of the substrate 11 being worked, i.e. the positive z direction facing outward from the side of the substrate 11 being worked. Converse interpretation should be given to terms such as “under” or “below”, etc.

At step S1 the method comprises providing the substrate 11. The substrate 11 may comprise one or more constituent layers. It is preferably a dielectric or other insulator, or at least has a substantially greater band gap (i.e. is more insulating) than the semiconductor material 16 that will be used for the nanowire cores. The substrate 11 comprises a crystalline substrate material (at least in areas upon which the semiconductor 16 is to be grown), e.g. InP (Indium Phosphide). InP is a semiconductor but has a significantly bigger band gap than, say, InSb, and therefore it can act as an insulating material in such a context. More generally this substrate material could be any insulator or relatively insulating material, e.g. GaAs, GaSb or Si. In embodiments the substrate material 11 is monocrystalline. In embodiments the crystalline structure of the substrate material is a zincblende structure (named after the crystal lattice structure found in the mineral zincblende, though this does not imply the use of the mineral zincblende itself nor the presence of zinc).

At step S2, the method comprises adding a first layer of mask material 12, e.g. silicon nitride, silicon oxide, aluminium oxide, hafnium oxide or boron nitride. The mask material is amorphous (i.e. non crystalline) as it will provide the mask for a subsequent selective area growth (SAG) step (of the walls 18).

At step S3, the method comprises patterning the mask material of the first layer 12. This may comprise etching away parts of the mask to leave a pattern openings where the shadow walls 18 are to be formed. Note however that the areas of the substrate 11 where the semiconductor 16 of the nanowires is to be formed are not left exposed by the pattern of first openings. Thus those areas are not etched.

At step S4 the wall material 18 is formed in the openings through the first mask 12 in order to form one or more shadow walls. This is performed using selective area growth (SAG), with the surface of the substrate 11 exposed by these openings acting as the seed crystal for epitaxial growth of the wall material 18. As such the wall material 18 is chosen to be crystalline also. In embodiments the wall material 18 may have a zincblende crystal structure to match the crystal structure of the substrate 11. However other crystal matching combinations are possible.

The wall material 18 is crystalline. It is not necessary for the walls to be monocrystalline, but in practice they may be. The wall material 18 may be a semiconductor, or alternatively a dielectric or other insulator. In embodiments the wall material is InP. At least in the illustrated embodiments, it is not important for the wall material 18 to be insulating, since it will not be in contact with the actual components of the final structure. In embodiments InP is chosen because the substrate is as well, but one could equally use e.g. InAs, GaAs, etc. for the walls instead.

In embodiments each wall 18 is between 10 and 500 nm wide, mainly for sturdiness of the wall in the next processing steps. There is no strict limit on the width of the walls 18. They can be over 1 µm wide and still grow fine, but this may become undesirable from a practical point of view as it consumes more material, and doesn’t offer any advantages in exchange. The height depends on the desired shadow region to be created and the angle of the beam used in the angled deposition, but in practice the wall height will be between 100 nm and several µm, up to around 12 µm.

At step S5 the first mask 12 is removed. This may be performed using any suitable known chemical processing step. In embodiments it is performed using a non-directional wet etching method to remove the mask material 12, such as buffered HF (buffered hydrofluoric acid). It is not essential in all possible implementations of the disclosed method to remove the first mask 12. However, if the first mask 12 is removed then this gives more control for the next patterning step. The reason for this is that it is desirable for the second mask 14 to be covering the walls 18 as well and avoid growth of the semiconductor 16 on the walls. One could in principle add the second mask 14 just on top of the first mask 12, but this would make a thicker mask layer to etch through for the growth of the semiconductor wire and this is undesirable.

At step S6, the method comprises forming a second layer of mask material 14, e.g. silicon nitride, silicon oxide, aluminium oxide, hafnium oxide or boron nitride. The mask material is again amorphous (i.e. non crystalline) as it will provide the mask for a subsequent selective area growth (SAG) step, this time of the nanowire cores 16. The same or a different mask material could be used compared to the first mask 12. The layer of second mask material 14 is deposited over the substrate 11 and over the walls 18. The one or more walls 18 coated with the second mask material 14 forms an overall shadow wall structure 19.

At step S7, the method comprises patterning the second mask 14 to form openings through the second mask. These openings are formed in different places over the substrate than the openings in the first mask 12. The openings in the second mask define where the semiconductor 16 cores of the nanowires will be formed.

At step S8 the method comprises growing the semiconductor 16 of the nanowires in the openings in the second mask 14. In embodiment the pattern defines a network of nanowire cores. This is again performed by SAG. In embodiments the width of the openings in the second mask 14, and therefore the width of the nanowires cores 16, is between 20 nm and 100 nm. They can be as long as desired for the design of the application in question. There is no strict limit on the width, but after about 100 nm the effect of 1D confinement for forming MZMs starts to diminish.

The semiconductor material 16 of the nanowires is crystalline, preferably monocrystalline. In embodiments the semiconductor 16 of the nanowires is a iii-v semiconductor, e.g. InSb, InAs, InP or GaAs. In an alternative example it could be silicon (Si). In a particular embodiment the semiconductor 16 is the iii-v semiconductor InSb. In embodiments the semiconductor 16 used for the nanowires has a zincblende crystal structure in order to provide good crystal matching with the substrate 11 on which it is grown. However other suitably matched crystal structures are possible. The semiconductor 16 of the nanowires also has a smaller bandgap than any insulators or dielectrics used for such properties elsewhere in the device, such as the substrate 11.

In embodiments the second mask 14 is simply left in place after step S8. Removing it would require extra processing which is unnecessary and it would be difficult to do without damaging the wires. However it is not excluded in all possible embodiments that the second mask could be removed between steps S8 and S9.

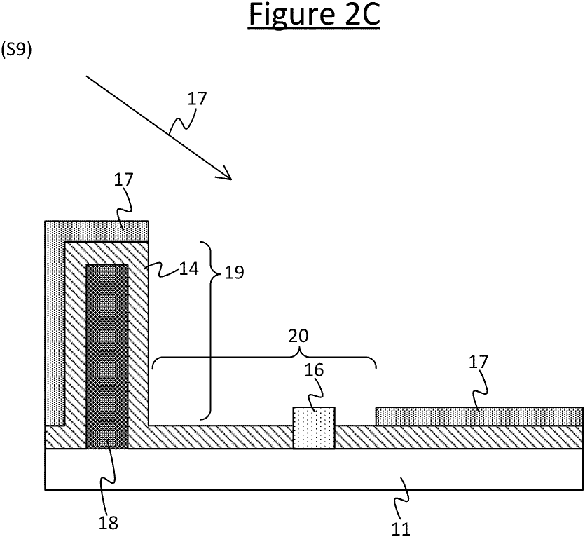

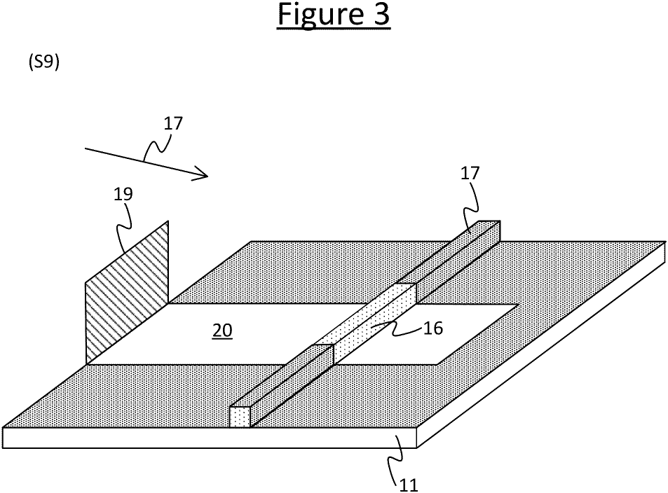

At step S9 the superconducting coating 17 is formed over at least part of each nanowire core 16. FIG. 3 gives a schematic isometric view of the device in fabrication at step S9.

Any superconducting material could be used, e.g. Al, Pb, Sn or Nb. In embodiments Al is used. It is deposited by angled deposition, whereby a beam of the material being deposited (in this case the superconductor 17) is directed toward the substrate 11 at a non-zero acute angle to the normal of the substrate 11 (on the side being worked, i.e. the side on which the mask 14 and semiconductor 16 are also formed). Any a directional deposition technique can be used, e.g. molecular beam epitaxy. Because of the angle, some areas 20 over the substrate 11, but not others, are shadowed from receiving the coating of the deposited material 17, being shadowed by the shadow wall structures 19 formed from the walls 18. These areas 20 may be referred to as shadow regions. I.e. because of the angle of the deposition beam, some regions over the substrate 11 are blocked by the shadow wall structure 19 from being coated. Thus by the design of a suitable shadow wall structure 19, it is possible to create nearly any patterning of the superconducting layer 17 that is desired for the application in question, such as to form superconducting islands over the nanowire cores 16.

For instance, the MZMs form at the endpoints of the semiconductor/superconductor heterostructure of the nanowire where the semiconductor and superconductor meet. Therefore to delineate the nanowire wire, an area is required beyond the end of the heterostructure where the semiconductor is not covered by a superconductor. So in the example of FIGS. 2C and 3, the shadow region 20 may form a break between two nanowires formed using the same length of semiconductor 16.

The angle of the deposition beam depends on the height of the walls 18 and the length of the desired shadow region(s) 20. In practice the beam will be less than 89 degrees to the plane of the substrate (more than 1 degree to the normal), and in an example set-up the beam may be less than 60 degrees to the plane of the substrate (more than 30 degrees to the normal), and the wall height may be between 100 nm and 12 µm. However this is just because of the design of a particular example tool being used and particular pattern being formed of deposition material 17. The wall height is related to the angle of deposition and the shadow length desired to be created. Different wall heights and deposition angles can be used depending on the deposition tool and desired pattern to be formed.

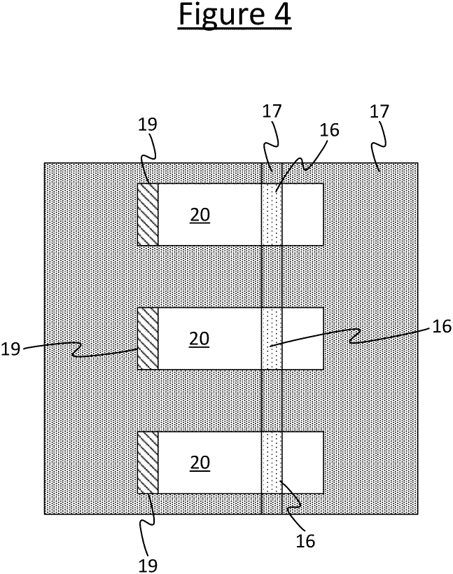

FIG. 4 schematically illustrates a top-down view of an extended design involving at least two nanowires bounded by at least three shadow regions 20, each formed by a respective shadow wall of the wall structure 19.

FIG. 5 shows an actual example of the design shown schematically in FIG. 4. In FIG. 5, panel (a) is a scanning electron micrograph of epitaxial growth of Al islands on in-plane InSb nanowires. InP walls are used to selectively shadow the superconductor during the deposition. Panel (b) gives a focussed ion beam cross section cut (through the line labelled b in panel a) showing the nanowire and the two Al islands. Panel (c) is a high resolution TEM micrograph of the nanowire (of the box labelled c in panel b), showing the abrupt transition between the shadowed and the Al covered region.

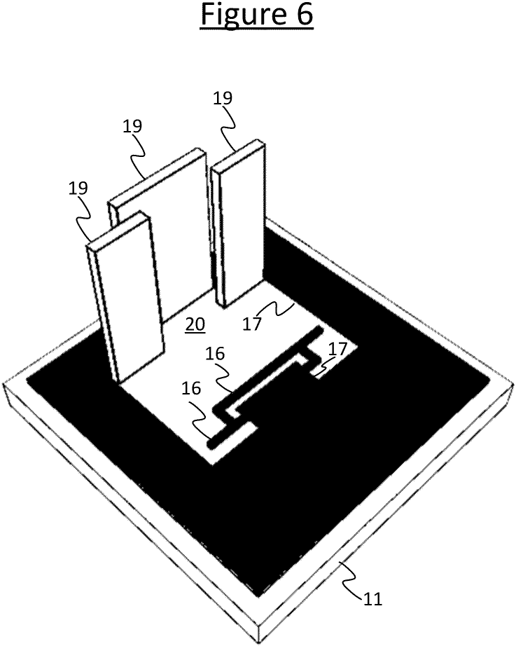

By way of further example, FIG. 6 schematically illustrates a more complex design with the semiconductor 16 formed in a loop, which is used in particular example quantum computing application. One length of semiconductor 16 on one side of the loop nearest the shadow wall structure 19 falls entirely in the shadow region 20, and is thus not coated. Another length of semiconductor on the other side of the loop has a portion of its length falling outside the shadow region 20, and is thus coated with the superconductor 17, thus forming a semiconductor-superconductor nanowire heterostructure. Other parts along the length of that nanowire are however shadowed by the wall structure 19, and are thus not coated.

By contrast with the methods disclosed above, in an existing method, shadow walls can be formed from the mask material 14. However, this requires two selective mask etching steps. The process needs to start with a very thick layer of mask material, then perform a first etch stage to etch that to the depth of the walls 18, and then a second etch stage to etch the openings in which to form the nanowires. This is harder to control, increasing the chance of inflicting damage at the surface. The walls will be relatively high, and thus the etching to define them will be deep, compared to the depth of the openings in which the semiconductor 16 will be grown. It is difficult to control the etching of several hundreds of nm of mask material such as SiN without damaging the underlying substrate.

In the presently disclosed approach there are also two etching steps: one to remove the first mask 12, and the other to pattern the second mask 14. However, when removing the first mask 12, there is no need to etch only a selected area (e.g. to create openings or walls out of the mask material). Rather, the entire mask 12 is simply lifted off indiscriminately (non-selectively as to area). In this case one can use non-directional wet etching methods to remove the mask material (e.g. buffered HF). This is highly selective as to the type of material removed (but not area removed), and thus causes no significant damage to the substrate surface underneath.

It would also be possible to form the walls 18 and the semiconductor cores 16 of the nanowires in the same SAG stage. However, the two-stage approach disclosed herein has two main advantages. The first is that it gives more control over the wall height and the wire diameter. This is limited in the one-stage approach as longer growth time needed for higher walls will also lead to overgrowth of the in-plane wires. High walls are beneficial for being able to shadow larger networks. And wires with a small diameter are important for the quantum confinement.

The second advantage is that the two-stage allows more flexibility in choice of materials. The one-stage approach limits to the same material being used for wall and nanowire. It is difficult to find materials that can be grown in-plane as well as out of plane at the same growth conditions. The two stage approach, on the other hand, allows the use of any material that can be grown in-plane without having to worry about being able to grow the walls simultaneously.

Thus the disclosed approach of the two-stage SAG method, with a separate SAG stage for forming the walls, provides a beneficial alternative to other possible methods of forming shadow walls.

It will be appreciated that the above embodiments have been described by way of example only.

More generally, according to one aspect disclosed herein, there is provided a method of fabricating a device, the method comprising: forming a first layer of amorphous mask material over a substrate; patterning the first layer of mask material over the substrate to form a first mask having a pattern of one or more first openings therethrough, the substrate having a crystalline surface at least in some areas including areas exposed by the openings; forming one or more shadow walls in the openings of the first mask by selective area growth of a first crystalline material; forming a second layer of amorphous mask material over the substrate and shadow walls; patterning the second layer of mask material to form a second mask having a pattern of one or more openings therethrough, the substrate having a crystalline surface also in areas exposed by the second openings; forming a second crystalline material in the openings of the second mask by selective area growth; and depositing a layer of deposition material by angled deposition over parts of the substrate, shadow walls and second crystalline material, whereby regions shadowed by the shadow walls are left uncoated.

In embodiments, the method may comprise removing the first mask before forming the layer of second mask material.

In embodiments the second mask may be left in place when the deposition material is deposited.

In embodiments the first and second crystalline materials may be different materials. Alternatively it is not excluded that the same material could be used.

In embodiments the crystalline surface of the substrate may have a zincblende crystal structure.

In embodiments the second crystalline material may have a zincblende crystal structure.

In embodiments the second crystalline material may be a semiconductor.

In embodiments the semiconductor material may be a iii-v semiconductor.

In embodiments, the second crystalline material may be one of InSb, InAs, InP, GaAs, or Silicon. In some particular embodiments the semiconductor is InSb.

In embodiments the first crystalline material may be a semiconductor.

In embodiments, the first crystalline material may be a first semiconductor material and the second crystalline material may be a second semiconductor material other than the first semiconductor material.

In embodiments the first crystalline material may be InP. In embodiments the second crystalline material may be a semiconductor other than InP. In some such embodiments the second material may be InSb.

In embodiments the first crystalline material may be the same material as at least the crystalline surface of the substrate. Alternatively a different material could be used.

In embodiments the deposition material may be a metal.

In embodiments the deposition material may be a conductor.

In embodiments the deposition material may be a superconducting material.

In embodiments the deposition material may be one of: Al, Pb, Sn or Nb. In some particular embodiments the deposition material is Al.

In embodiments, the first and second mask materials may be the same material. Alternatively it is not excluded that different materials could be used.

In embodiments, each of the first and second mask materials may be a dielectric or other insulator.

In embodiments, each of the first and/or second mask materials may be one of: silicon nitride, silicon oxide, aluminium oxide, hafnium oxide or boron nitride. In some particular embodiments the first and second mask materials are silicon nitride.

In embodiments the substrate may be a semiconductor, or a dielectric or other insulator. In embodiments the substrate may be one of: InP, GaAs, GaSb or Si.

In embodiments, at least the growth of the first crystalline material, the formation of the layer of second mask material, the patterning of the second mask, the growth of the second crystalline material, and the deposition of the deposition material, may all be performed in situ in the same vacuum chamber, or vacuum chambers connected by one or more vacuum tunnels, without breaking vacuum. In some such embodiments the formation of the layer of first mask material and the patterning of the first mask may also be performed in situ.

In embodiments, the second crystalline material may be a semiconductor, and the forming of the second crystalline material may comprise forming one or more lengths of this semiconductor. In such embodiments, the deposition material may comprise a superconducting material, and the deposition may comprise coating at least parts of the one or more lengths of semiconductor with the superconducting material, thus forming one or more semiconductor-superconducting nanowires suitable for inducing majorana zero modes.

According to another aspect disclosed herein there is provided a device fabricated by any embodiment of the method disclosed herein.

According to another aspect, there is provided a method of operating a device fabricated according to any of the embodiments disclosed herein, this method comprising: cooling the device to a temperature where the superconductor becomes superconducting, applying a magnetic field from an internal or external source, and applying an electrostatic potential to the gates in order to induce majorana zero modes in at least one of the nanowires.

Other variants or use cases of the disclosed techniques may become apparent to the person skilled in the art once given the disclosure herein. The scope of the disclosure is not limited by the described embodiments but only by the accompanying claims.

1-15. (canceled)

16. A method of fabricating a device, the method comprising:
forming a first layer of amorphous mask material over a substrate;
patterning the first layer of mask material over the substrate to form a first mask having a pattern of one or more first openings therethrough, the substrate having a crystalline surface at least in some areas including areas exposed by the openings;
forming one or more shadow walls in the openings of the first mask by selective area growth of a first crystalline material;
forming a second layer of amorphous mask material over the substrate and shadow walls; patterning the second layer of mask material to form a second mask having a pattern of one or more openings therethrough, the substrate having a crystalline surface also in areas exposed by the second openings;
forming a second crystalline material in the openings of the second mask by selective area growth; and
depositing a layer of deposition material by angled deposition over parts of the substrate, shadow walls and second crystalline material, whereby regions shadowed by the shadow walls are left uncoated.

17. The method of claim 16, comprising removing the first mask before forming the layer of second mask material.

18. The method of claim 16, wherein the second mask is left in place when the deposition material is deposited.

19. The method of claim 16, wherein the first and second crystalline materials are different materials.

20. The method of claim 16, wherein the second crystalline material is a semiconductor.

21. The method of claim 20, wherein the semiconductor material is a iii-v semiconductor.

22. The method of claim 20, wherein the second crystalline material is one of InSb, InAs, InP, GaAs, or Silicon.

23. The method of claim 16, wherein the first crystalline material is a semiconductor.

24. The method of claim 23, wherein the first crystalline material is a first semiconductor material and the second crystalline material is a second semiconductor material other than the first semiconductor material.

25. The method of claim 16, wherein the deposition material is a metal.

26. The method of claim 16, wherein the deposition material is a conductor.

27. The method of claim 16, wherein the deposition material is a superconducting material.

28. The method of claim 27, wherein the deposition material is one of: Al, Pb, Sn or Nb.

29. The method of claim 16, wherein the first and second mask materials are the same material.

30. The method of claim 16, wherein each of the first and second mask materials is a dielectric or other insulator.

31. The method of claim 16, wherein each of the first and/or second mask materials is one of: silicon nitride, silicon oxide, aluminium oxide, hafnium oxide or boron nitride.

32. The method of claim 16, wherein at least the growth of the first crystalline material, the formation of the layer of second mask material, the patterning of the second mask, the growth of the second crystalline material, and the deposition of the deposition material, are all performed in situ in the same vacuum chamber, or vacuum chambers connected by one or more vacuum tunnels, without breaking vacuum.

33. The method of claim 16, wherein the second crystalline material is a semiconductor, and the forming of the second crystalline material comprises forming one or more lengths of this semiconductor; and wherein the deposition material comprises a superconducting material, and the deposition comprises coating at least parts of the one or more lengths of semiconductor with the superconducting material, thus forming one or more semiconductor-superconducting nanowires suitable for inducing majorana zero modes.

34. A device fabricated by the method of claim 16.

35. A method of operating the device fabricated according to claim 34, comprising: cooling the device to a temperature where the superconductor becomes superconducting, applying a magnetic field from an internal or external source, and
applying an electrostatic potential to the gates in order to induce majorana zero modes in at least one of the nanowires.
